(19) United States
(12) Patent Application Publication
(10) Pub. No.: US 2010/0240220 A1
(43) Pub. Date: Sep. 23, 2010

(54) PROCESS FOR STRIPPING PHOTORESIST AND REMOVING DIELECTRIC LINER

(75) Inventors: Yi-Wei CHIU, Kaohsiung (TW); Yih Song CHIU, Hsinchu (TW); Tzu Chan WENG, Kaohsiung City (TW); Jeng Chang HER, Tainan City (TW)

Correspondence Address: LOWE HAUPTMAN HAM & BERNER, LLP, 1700 DIAGONAL ROAD, SUITE 300, ALEXANDRIA, VA, 22314, US

(73) Assignee: TAIWAN SEMICONDUCTOR MANUFACTURING COMPANY, LTD., Hsinchu (TW)

(21) Appl. No.: 12/721,961

(22) Filed: Mar. 11, 2010

Related U.S. Application Data
(60) Provisional application No. 61/162,037, filed on Mar. 20, 2009.

(51) Int. Cl. H01L 21/3065

(52) U.S. Cl. 438/714; 257/E21.218

(57) ABSTRACT

A process of stripping a patterned photoresist layer and removing a dielectric liner includes performing an oxygen-containing plasma dry etch process and performing a fluorine-containing plasma dry etch process in the same reaction chamber at a process temperature less than 120° C.

### TECHNICAL FIELD

The present disclosure relates to plasma strip process used in the manufacture of semiconductor integrated circuits, and more particularly, to a process for stripping photoresist and removing a liner in one plasma reaction chamber.

### BACKGROUND

Downstream stripping processes with wafer temperatures usually above about 250° C., typically using oxygen as a principal gas, have been prevalent for all major photoresist removal applications in transistor fabrication as part of IC manufacturing. The currently used PR stripping process may be performed in one or two parts and is generally performed in a different chamber than the silicon dioxide etching process. A conventional stripping and residue removal process, performed following the contact and stop layer etching, generally uses mostly oxygen gas fed to a plasma source, and may use wet chemicals or have a small amount of forming gas or fluorinated gas added in a second step to remove residues. The traditional photoresist-removal process uses an oxygen-based plasma at a high temperature, that is, on the order of 250° C., such as about 250° C. to about 270° C. However, under some circumstances, using higher temperatures to remove the photoresist may make some of the other contaminants, particularly the polymer residues, more difficult to remove. In addition, the wet clean process tends to affect material properties such as via corrosion of metal, particularly with copper, and changes in dielectric constant value, particularly with low-k dielectric materials.

The current processes for stripping photoresist and etching stop layer are detrimental to device performance and that there remains a need for improvement.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIGS. 1 to 3 illustrate the process flow sequence for the embodiment of the present invention; and

FIG. 4 is a flow chart illustrating sequential steps in a method according to an embodiment of the present invention.

### DETAILED DESCRIPTION OF ILLUSTRATIVE EMBODIMENTS

In the following description, numerous specific details are set forth to provide a thorough understanding of the present disclosure. However, one having an ordinary skill in the art will recognize that the embodiments can be practiced without these specific details. In some instances, well-known structures and processes have not been described in detail to avoid unnecessarily obscuring descriptions.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

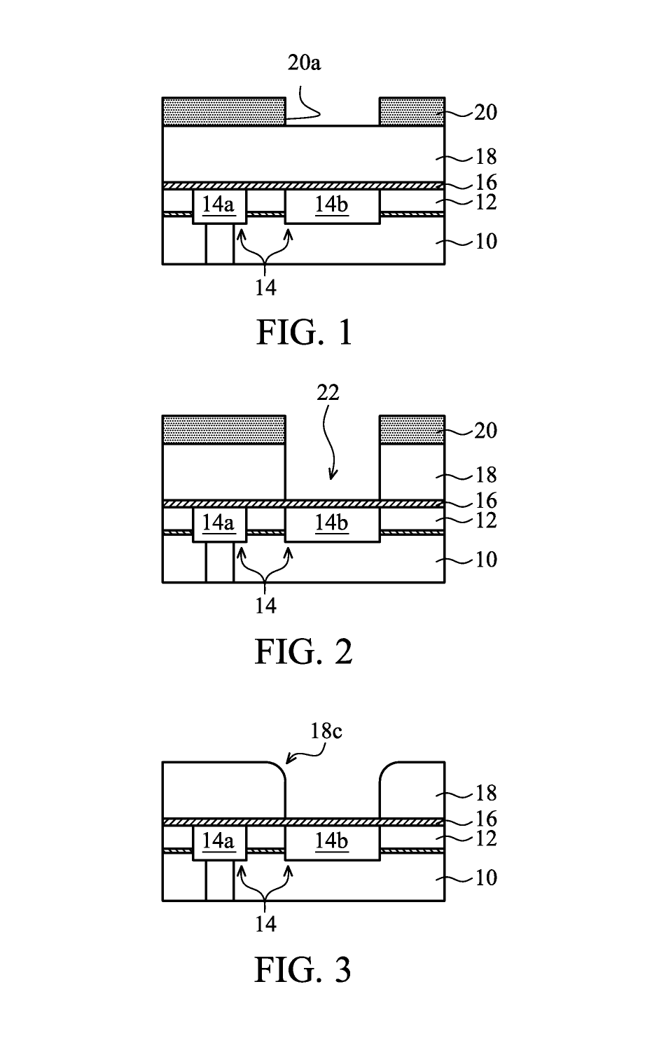

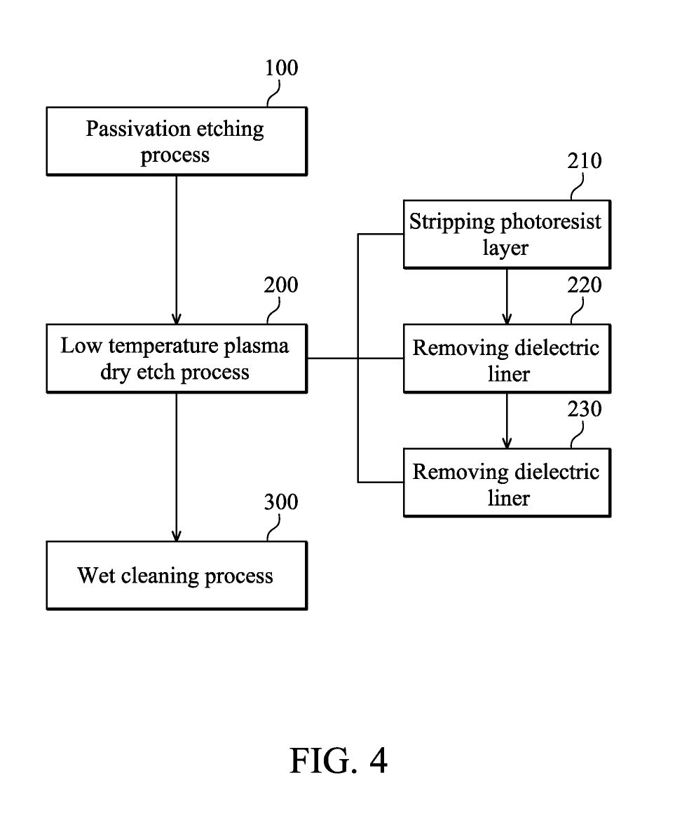

The application discloses a process of striping photoresist and removing dielectric liner in a plasma dry etch reaction chamber, which can be applied to any process for forming conductive structures (e.g., metal interconnects, metal lines, or metal gates) and devices (e.g. memory devices, logic devices, power devices, image sensors, or microprocessors). In a specific embodiment, it is an all-in-one process of striping photoresist and removing dielectric liner in a plasma dry etch reaction chamber. Herein, cross-sectional diagrams of FIG. 1 to FIG. 3 illustrate an exemplary embodiment of a process of stripping photoresist and removing a dielectric liner after etching a passivation layer for defining a desired bonding pad configuration. The processes described in FIG. 1 to FIG. 3 proceed in accordance with the steps set forth in the flow chart of FIG. 4.

FIG. 1 is a cross-sectional view of an example of an integrated circuit substrate 10 used for interconnection fabrication. The substrate 10 may comprise a semiconductor substrate as employed in a semiconductor integrated circuit fabrication, and integrated circuits may be formed therein and/or thereupon. The semiconductor substrate is defined to mean any construction comprising semiconductor materials including, but is not limited to, bulk silicon, a semiconductor wafer, a silicon-on-insulator (SOI) substrate, or a substrate comprising Ge, GaAs, GaP, InAs, and/or InP. The integrated circuits as used herein refer to electronic circuits having multiple individual circuit elements, such as transistors, diodes, resistors, capacitors, inductors, and/or other active and passive semiconductor devices. These partially completed circuits are then interconnected to complete the integrated circuit by using a multilevel of patterned conducting layers with alternating insulating layers. The multilevel metal interconnect structure is not described in detail to simplify the drawings and the discussion.

As shown in FIG. 1, on the substrate 10, an inter-metal dielectric (IMD) layer 12 is fabricated as a top-level IMD layer, and a top-level metal layer 14 is formed in the IMD layer 12. The IMD layer 12 has a thickness of about 1000 angstroms to about 20000 angstroms through any of a variety of techniques including spin coating, CVD, and/or future-developed deposition procedures. In some embodiments, the IMD layer 12 may comprise SiO₂, SiN_{X}, SiON, PSG, BPSG, F-containing SiO₂, or various types of low-k films of a comparatively low dielectric constant dielectric material with a k value less than about 3.9, e.g., 3.5 or less. In some embodiments, a wide variety of low-k materials may be employed in accordance with embodiments of the present invention, for example, spin-on inorganic dielectrics, spin-on organic dielectrics, porous dielectric materials, organic polymer, organic silica glass, fluorinated silicate glass (FSG), diamond-like carbon, HSQ (hydrogen silsesquioxane) series material, MSQ (methyl silsesquioxane) series material, or porous organic series material.

The top-level metal layer 14 has a pattern 14a used for interconnecting lines and a pattern 14b used for a contact pad. The pattern 14a is connected to other lines by interconnects and/or vias. The pattern 14b is a terminal contact region, which is a portion of conductive routes and has an exposed surface in electrical communication with a bonding pad. In some embodiments, the metal layer 14 may be treated by a planarization process, such as chemical mechanical polishing (CMP), achieving a planarized surface co-planar with the IMD layer 12. In some embodiments, suitable materials for the metal layer 14 may include, but are not limited to, for example copper, copper alloy, aluminum, copper-doped aluminum, refractory metal, or other copper-based conductive materials.

Referring to FIG. 1, a dielectric liner 16 is formed on the IMD layer 12 and the top-level metal layer 14, and a passivation layer 18 is then applied on the dielectric liner 16 to passivate the substrate 10 from moisture and contamination, followed by providing a patterned photoresist layer 20 with an opening 20a on the passivation layer 18 for defining a bonding pad window.

In some embodiments, the dielectric liner 16 may function as an anti-reflective layer and/or an etch stop layer, which is not particularly limited and generally ranges from 50-2500 Angstroms. In one embodiment, the dielectric liner is a silicon oxynitride (SiON) layer deposited by a CVD or PVD method. In other embodiments, the dielectric liner 16 may be silicon nitride or other dielectric material known to those skilled in the art.

The passivation layer 18 comprises at least one material that is capable of preventing moisture or ions from contacting the top-level metal layer 14, such as silicon oxide or silicon nitride. In some embodiments, the passivation layer 18 may be formed in a single-layer form or a multi-layer structure including any one of TEOS oxide, silicon nitride, and plasma enhanced silicon oxide. In one embodiment, the passivation layer 18 is formed of a combination of two dielectric layers, such as a silicon oxide layer deposited using plasma enhanced chemical vapor deposition (PECVD) technology and an overlying silicon nitride layer deposited by conventional processes, such as a low pressure chemical vapor deposition, an ultraviolet nitride process, or a PECVD process. In one embodiment, the passivation layer 18 is formed of a combination of four dielectric layers, such as an oxide/nitride/oxide/nitride structure.

The photoresist layer 20 is formed on the upper surface of the passivation layer 18 by spin coating. The coated photoresist layer 20 is then patterned by a photolithography process, such as UV light lithography or other suitable process to leave exposed portions of the passivation layer 18, forming an opening 20a corresponding to a desired bonding pad configuration.

Referring to FIG. 2, at step 100 of passivation etching process, the passivation layer 18 is etched using the photoresist layer 20 pattern as an etch mask to leave exposed portions of the dielectric liner 16, forming an opening 22 in the passivation layer 18 corresponding to a desired bonding pad window. For example, the passivation layer 20 is anisotropically etched using a RIE etch with a fluorine containing gas. For etching an oxide layer, Ar/CF₄ is used as an etchant at a temperature of between about 100 and 200° C. and a pressure of between about 0.1 and 0.5 Ton using a dry etch process. For etching a Si₃N₄ layer, He/NF₃ is used as an etchant at a temperature of between about 50 and 150° C. and a pressure of between about 1.0 and 1.5 Torr using a dry etch process.

Referring to FIG. 3, at step 200 of low temperature plasma dry etch process, a process of stripping the photoresist layer 20 and etching the exposed portion of the dielectric liner 16 is performed in the same reaction chamber in which a dry etch involving a low temperature plasma process. The term “low temperature” refers to the plasma process is performed at a temperature less than about 120° C., for example, about 10° C. to about 90° C. First, at step 210 of stripping photoresist, a low temperature oxygen-containing dry plasma process is performed to remove a majority of the photoresist and residue. Using a low temperature photoresist strip can provide efficient stripping while preventing residues from being baked on. In one embodiment, for stripping the photoresist layer 20, at a temperature about 20° C. to 30° C. and a pressure between about 20 to 60 mTorr, an O₂ gas is supplied to the reaction chamber at a flow rate of 200-600 Standard Cubic Centimeters per Minute (sccm), and the RF power is applied at a level of about 50 to 1000 Watts (W). Second, at step 220 of removing dielectric liner, a low temperature fluorine-containing dry plasma process is performed in the same reaction chamber to remove the exposed portion of the dielectric liner 16, exposing the pattern 14b of the top-level metal layer 14. In one embodiment, for etching the dielectric liner 16, at a temperature about 20° C. to 30° C. and a pressure between about 10 to 50 mTorr, CF₄ gas is supplied to the reaction chamber at a flow rate of 100-300 sccm, CHF₃ gas is supplied to the reaction chamber at a flow rate of 20-60 sccm, and the RF power is applied at a level of about 50 to 1000 W. Further, at step 230 of reducing oxidized copper, a low temperature hydrogen-containing dry plasma process is optionally performed for recovering copper oxidation. For example, at a temperature about 20° C. to 30° C. and a pressure between about 5 to 80 mTorr, H₂ gas is supplied to the reaction chamber at a flow rate of 200-600 sccm, N₂ gas is supplied to the reaction chamber at a flow rate of 10-40 sccm, Ar gas is supplied to the reaction chamber at a flow rate of 50-300 sccm, and the RF power is applied at a level of about 50 to 600 W.

Compared with the conventional method of integrating a high temperature photoresist strip process and a dielectric liner dry etch process in different tools, the disclosed process of stripping photoresist and removing a dielectric liner in the same low temperature plasma dry etch chamber can save at least three process cycles, which is simpler and has lower production cost. The low temperature plasma strip process can remove the majority of etch residues and recover copper oxidation, and make the bonding pad center being free of hump. In addition, the disclosed process can form a corner rounding profile 18c on the top corner of the passivation layer 18, thus improving junction leakage and isolation characteristics.

After the photoresist layer, the dielectric liner, and the majority of etch residue have been removed during the plasma strip process, it may be optional to further clean any remaining residues that may exist on the substrate 10 using a wet cleaning process 300. The implementation of this post-strip cleaning process will depend upon particular device application and process needs. In one embodiment, this wet cleaning process involves either an acidic or basic solution. In one embodiment, the wet cleaning process is simply a deionized water cleaning process. In some embodiments, the wet cleaning processes involve the use of organic additives. After the wet clean has been performed, the flow chart of FIG. 4 is complete.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A method, comprising:
providing a semiconductor substrate comprising a conductive layer, a dielectric liner formed on the conductive layer, a passivation layer formed on the dielectric liner and a photoresist layer formed on the passivation layer, wherein the photoresist layer has a first opening exposing a portion of the passivation layer;
etching the exposed portion of the passivation layer using the photoresist layer as the mask, forming a second opening in the passivation layer and exposing a portion of the dielectric liner; and
performing a plasma dry etch process at a temperature less than 120° C. to remove the photoresist layer and the exposed portion of the dielectric liner in the same reaction chamber, exposing a portion of the conductive layer.

2. The method of claim 1, wherein the step of performing a plasma dry etch process comprises:
performing a oxygen-containing plasma dry etch process to remove the photoresist layer; and
performing a fluorine-containing plasma dry etch process to remove the exposed portion of the dielectric liner.

3. The method of claim 2, further comprising performing a hydrogen-containing plasma dry etch process.

4. The method of claim 2, wherein the step of performing a fluorine-containing plasma dry etch process comprising supplying CF₄ gas at a flow rate of 100-300 sccm and CHF₃ gas at a flow rate of 20-60 sccm.

5. The method of claim 1, wherein the plasma dry etch process is performed at a temperature between 10° C. and 30° C.

6. The method of claim 1, further comprising performing a wet cleaning process after performing a plasma dry etch process.

7. The method of claim 1, wherein the dielectric liner is a SiON layer.

8. The method of claim 1, wherein the conductive layer comprises copper.

9. The method of claim 1, wherein the passivation layer comprises at least an oxide layer and a nitride layer.

10. The method of claim 1, wherein after performing a plasma dry etch process, a corner rounding profile is formed on the top corner of the passivation layer.

11. A method, comprising:
providing a semiconductor substrate comprising a copper-containing conductive layer, a SiON liner formed on the copper-containing conductive layer, a passivation layer formed on the SiON liner and a photoresist layer formed on the passivation layer, wherein the photoresist layer has a first opening exposing a portion of the passivation layer, and the first opening corresponds in position to a bonding pad window;
etching the exposed portion of the passivation layer using the photoresist layer as the mask, forming a second opening in the passivation layer and exposing a portion of the SiON liner; and
performing a plasma dry etch process at a temperature less than 120° C. to remove the photoresist layer and the exposed portion of the SiON liner in the same reaction chamber, exposing a portion of the copper-containing conductive layer.

12. The method of claim 11, wherein the step of performing a plasma dry etch process comprises:
performing a oxygen-containing plasma dry etch process to remove the photoresist layer; and
performing a fluorine-containing plasma dry etch process to remove the exposed portion of the SiON liner.

13. The method of claim 12, wherein the step of performing an oxygen-containing plasma dry etch process comprises supplying O₂ gas at a flow rate of 200-600 sccm at a pressure between about 20 to 60 mTorr.

14. The method of claim 12, wherein the step of performing a fluorine-containing plasma dry etch process comprises supplying CF₄ gas at a flow rate of 100-300 sccm and CHF₃ gas at a flow rate of 20-60 sccm at a pressure between about 10 to 50 mTorr.

15. The method of claim 12, further comprising performing a hydrogen-containing plasma dry etch process to reduce oxidized copper.

16. The method of claim 15, wherein the step of performing a hydrogen-containing plasma dry etch process comprises supplying H₂ gas at a flow rate of 200-600 sccm, N₂ gas at a flow rate of 10-40 sccm and Ar gas at a flow rate of 50-300 sccm a pressure between about 5 to 80 mTorr, at a pressure between about 5 to 80 mTorr.

17. The method of claim 11, wherein the plasma dry etch process is performed at a temperature between 10° C. and 30° C.

18. The method of claim 11, further comprising performing a wet cleaning process to remove residues.

19. The method of claim 11, wherein the passivation layer comprises at least an oxide layer and a nitride layer.

20. The method of claim 11, wherein after performing a plasma dry etch process, a corner rounding profile is formed on the top corner of the passivation layer.
